(19) United States
(12) Patent Application Publication
(10) Pub. No.: US 2026/0164811 A1
(43) Pub. Date: Jun. 11, 2026

(54) ELECTROSTATIC DISCHARGE DEVICE UTILIZING BACKSIDE DOPED REGION AND BACKSIDE WIRING

(71) Applicant: INTERNATIONAL BUSINESS MACHINES CORPORATION, ARMONK, NY (US)

(72) Inventors: Masoud Zabihi, Schenectady, NY (US); Robert Gauthier, Williston, VT (US); Anindya Nath, Watervliet, NY (US); Anthony I-Chih Chou, Guilderland, NY (US)

(21) Appl. No.: 18/974,723

(22) Filed: Dec. 9, 2024

(51) Int. Cl. H10D 89/60

(52) U.S. Cl. CPC H10D 89/921; H10D 89/611; H10D 89/811

(57) ABSTRACT

A semiconductor device can include a top device, a bottom passive device, and a first well region and a second well region adjacent to each other and separating the top device from the bottom passive device.

### BACKGROUND

### Technical Field

The present disclosure generally relates to semiconductors, and more particularly, to electrostatic discharge device utilizing backside doped region and backside wiring structure, and methods of creation thereof.

### Description of Related Art

The continuous miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a top device, a bottom passive device, and a first well region and a second well region adjacent to each other and separating the top device from the bottom passive device.

In one embodiment, the bottom passive device includes a first doped region, a second doped region, a first backside contact below the first doped region, and a second backside contact below the second doped region. The first doped region and the second doped region are at least partially intruding into the first well region and the second well region, respectively.

In one embodiment, the bottom passive device includes a first metal interconnect below the first backside contact, a second metal interconnect below the second backside contact, and a backside interlayer dielectric isolating the first metal interconnect and the first backside contact from the second metal interconnect and the second backside contact.

In one embodiment, the top device is at least one of: a resistor, a field-effect transistor, and an N-type capacitor.

In one embodiment, at least one of the top device and the bottom passive device is an electrostatic discharge device (ESD).

In one embodiment, the top device includes at least one of: a bipolar junction and a diode.

In one embodiment, the top device includes a string of diodes with guard ring.

In one embodiment, the first well region is an N-well region and the second well region is a P-well region.

In one embodiment, the first doped region is a P-type doped region, and the second doped region is an N-type doped region.

According to an embodiment, a method for fabrication of a semiconductor device includes forming a top device, forming a bottom passive device, forming a first well region and a second well region adjacent to each other, and isolating the top device from the bottom passive device via the first well region and the second dwell region.

In one embodiment, forming the bottom passive device includes forming a first doped region, forming a second doped region, forming a first backside contact below the first doped region, forming a second backside contact below the second doped region, and at least partially extending the first doped region and the second doped region into the first well region and the second well region, respectively.

In one embodiment, the forming bottom passive device includes forming a first metal interconnect below the first backside contact, forming a second metal interconnect below the second backside contact, forming a backside interlayer dielectric, isolating the first metal interconnect and the first backside contact from the second metal interconnect and the second backside contact via the backside interlayer dielectric.

In one embodiment, the top device is at least one of: a resistor, a field-effect transistor, and an N-type capacitor.

In one embodiment, at least one of the top device and the bottom passive device is an electrostatic discharge device (ESD).

In one embodiment, the top device includes at least one of: a bipolar junction and a diode.

In one embodiment, forming the top device includes forming a string of diodes with guard rings.

In one embodiment, the method includes doping the first well region with an N-type dopant, and doping the second well region with a P-type dopant.

In one embodiment, the method includes doping the first doped region with an N-type dopant, and doping the second doped region with a P-type dopant.

According to an embodiment, a top electrostatic discharge device (ESD), and a bottom ESD device, wherein the top ESD device is built on a frontside of the semiconductor device and the bottom ESD device is built on a backside of the semiconductor device.

In one embodiment, the semiconductor device includes a first well region and a second well region adjacent to each other and separating the top ESD device from the bottom ESD device.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates an electrostatic discharge device.

FIG. 2A illustrates a cross-section of a semiconductor device with an electrostatic discharge device on the backside, in accordance with some embodiments.

FIG. 2B illustrates a cross-section of semiconductor device including an electrostatic discharge diode using backside wiring, in accordance with some embodiments.

FIGS. 2C-2D illustrate a string of diodes using backside wiring, in accordance with some embodiments.

FIGS. 3A-3B illustrate a semiconductor device after the front end of line processes, in accordance with some embodiments.

FIGS. 4A-4B illustrate a semiconductor device after the middle end of line and back end of line processes, in accordance with some embodiments.

FIGS. 5A-5B illustrate a semiconductor device after the removal of the substrate, in accordance with some embodiments.

FIGS. 6A-6B illustrate a semiconductor device after the removal of the etch stop layer, in accordance with some embodiments.

FIGS. 7A-7B illustrate a semiconductor device after the formation of the backside interlayer dielectric, in accordance with some embodiments.

FIGS. 8A-8B illustrate a semiconductor device after patterning of the backside doped regions, in accordance with some embodiments.

FIGS. 9A-9B illustrate a semiconductor device after the contact metallization, in accordance with some embodiments.

FIGS. 10A-10B illustrate a semiconductor device after the contact metallization, in accordance with some embodiments.

FIGS. 11A-11B illustrate a semiconductor device after the formation of additional interlayer dielectric, in accordance with some embodiments.

FIGS. 12A-12B illustrate a semiconductor device after the formation of backside interconnect, in accordance with some embodiments.

FIG. 13 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter can be combined with elements of different embodiments.

Backside interconnect technology is emerging as a preferred direction in the semiconductor industry. As the demand for smaller, faster, and more energy-efficient electronic devices grows, manufacturers are exploring innovative ways to enhance chip performance while reducing physical dimensions. Backside interconnects involve routing electrical connections on the reverse side of the semiconductor wafer, which can improve signal integrity, reduce power consumption, and allow for higher density of interconnections. This approach helps in mitigating issues such as signal delay and crosstalk that are prevalent in traditional front-side interconnects, especially as device geometries continue to shrink at the nanoscale level.

However, one of the challenges in optimizing chip design is that electrostatic discharge (ESD) protection devices occupy a considerable area footprint on the top wafer surface. ESD devices are components that protect sensitive semiconductor circuits from damage caused by sudden electrical surges or static electricity discharges during handling and operation. These protective elements, while essential, consume valuable real estate on the chip's front side, which could otherwise be utilized for additional circuitry or functional enhancements.

By adopting backside interconnect methodologies, designers can alleviate the space constraints imposed by ESD protection components. Relocating some interconnect layers to the backside allows for more use of the top wafer area, enabling the integration of more transistors or the addition of new features without increasing the overall chip size. This not only enhances the performance capabilities of the semiconductor devices but also contributes to cost savings by improving (e.g., maximizing) the utility of each wafer.

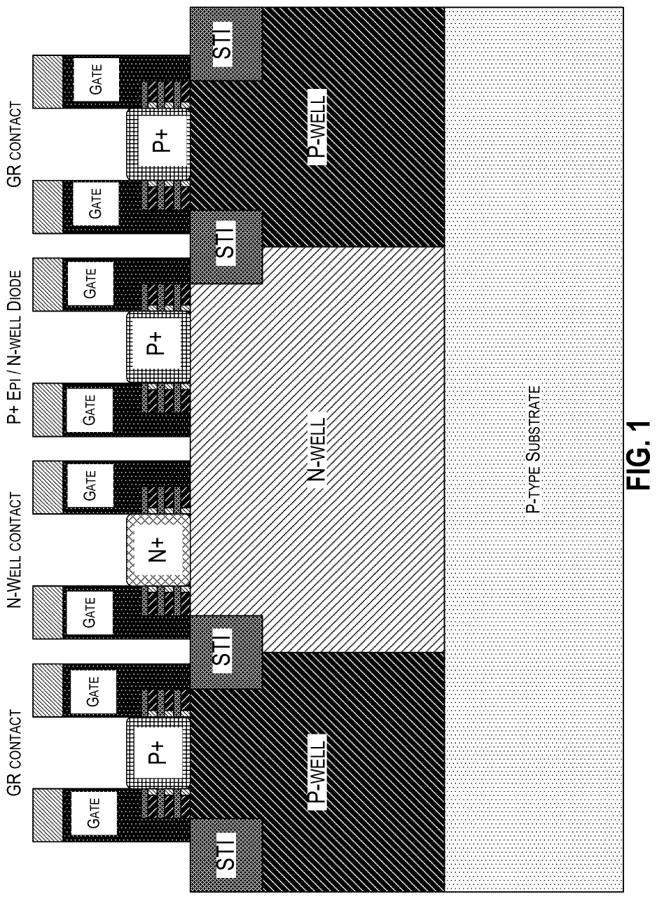

FIG. 1 illlustrates an ESD device built on a frontside of the semiconductor device. The ESD diode with a guard ring is typically built on the top (front) side of a semiconductor wafer. The ESD diode acts as a protective element that safeguards sensitive electronic components from sudden voltage spikes caused by electrostatic discharges. The guard ring encircling the diode enhances this protection by providing a controlled path for the discharge current, effectively isolating the ESD event and preventing it from affecting the critical areas of the integrated circuit. Building ESD devices on the front side occupies a significant area on the chip. This substantial area consumption is due to the physical space required not only for the ESD diode itself but also for the guard ring and necessary spacing from other components to avoid electrical interference. As semiconductor technologies advance towards higher integration and miniaturization, the real estate on the top side of the wafer becomes increasingly valuable. The large footprint of front-side ESD protection devices can limit the addition of more functional elements or require compromises in circuit design.

Disclosed is an ESD device structure, which utilizes a backside epitaxially grown doped region combined with backside wiring. The design aims to address the challenges of space constraints and performance limitations associated with traditional front-side ESD protection mechanisms in semiconductor devices. The components of the ESD device structure are the backside epitaxially grown doped region and the backside wiring. The epitaxial growth process involves depositing a crystalline layer of semiconductor material with controlled doping levels onto the existing wafer substrate's backside. Such a layer maintains the crystal orientation of the underlying material, ensuring high-quality electrical characteristics. The doped region introduces specific impurities to create either an N-type or P-type semiconductor layer, serving as an important part of the ESD protection by providing a pathway for excess charge to be safely dissipated during an ESD event.

Backside wiring entails creating conductive pathways on the wafer's reverse side to connect the backside doped regions to the rest of the circuit. This is achieved using metallization processes compatible with existing semiconductor fabrication techniques. The backside interconnects are aligned and connected to the front-side circuitry through vias or other vertical interconnect methods, ensuring seamless electrical integration. By relocating the ESD protection components to the backside, surface area on the top wafer is freed up, which allows for more active devices or additional functionalities to be included in the same chip area, enhancing layout flexibility. The disclosed device further improves electrical performance by offering shorter and more direct paths for ESD currents, potentially reducing response times during an ESD event. Additionally, it reduces parasitic effects that adversely affect high-speed or high-frequency circuit performance.

Thermal management is enhanced as well. The backside placement of ESD components allows heat generated during an ESD event to dissipate more efficiently, protecting sensitive front-side components from thermal damage. From a manufacturing standpoint, the use of epitaxial growth and backside wiring is compatible with standard semiconductor fabrication processes. This facilitates integration without significant changes to manufacturing workflows and potentially reduces manufacturing costs by optimizing the use of wafer real estate and enhancing yield through improved device protection.

Accordingly, the teachings herein provide methods and systems of formation of ESD devices with backside doped region and backside wiring structures. The techniques described herein may be implemented in a number of ways. Example implementations are provided below with reference to the following figures.

Example Semiconductor Device with Backside Doped Region and Backside Wiring Structure

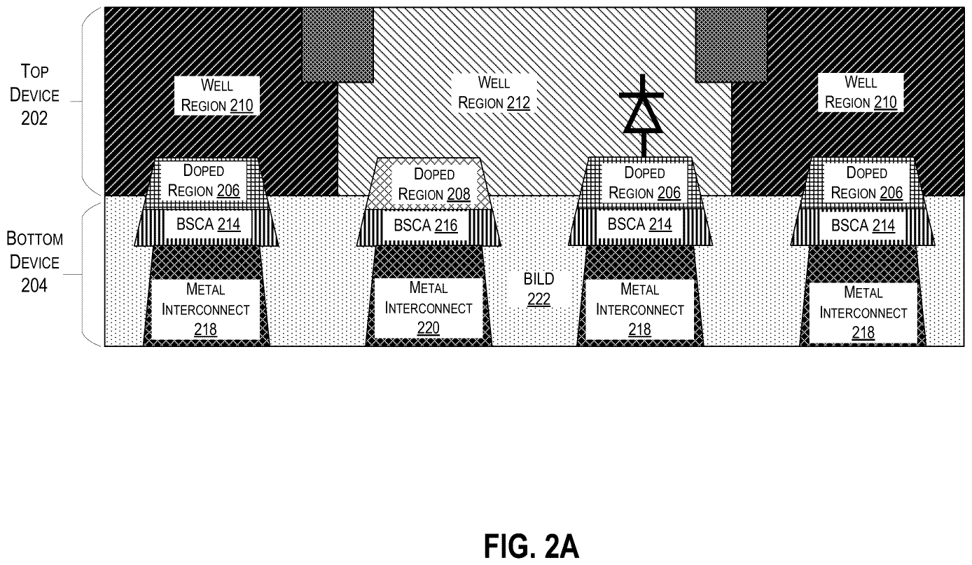

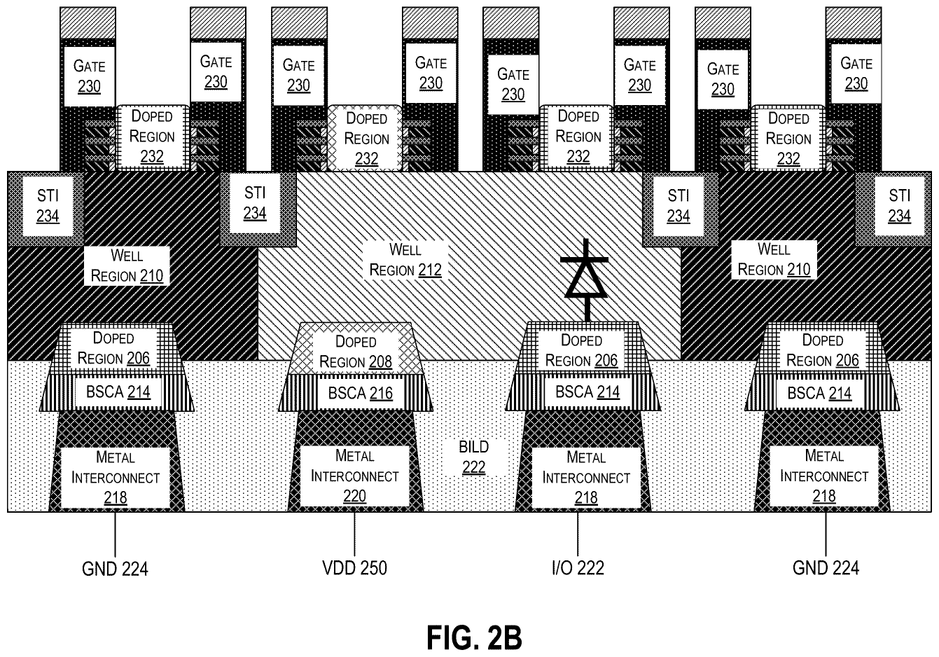

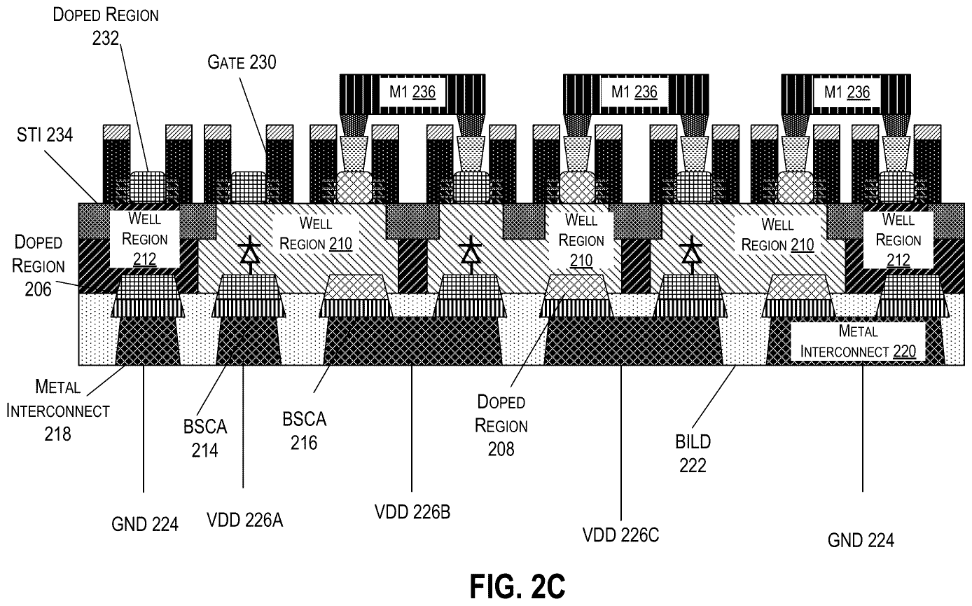

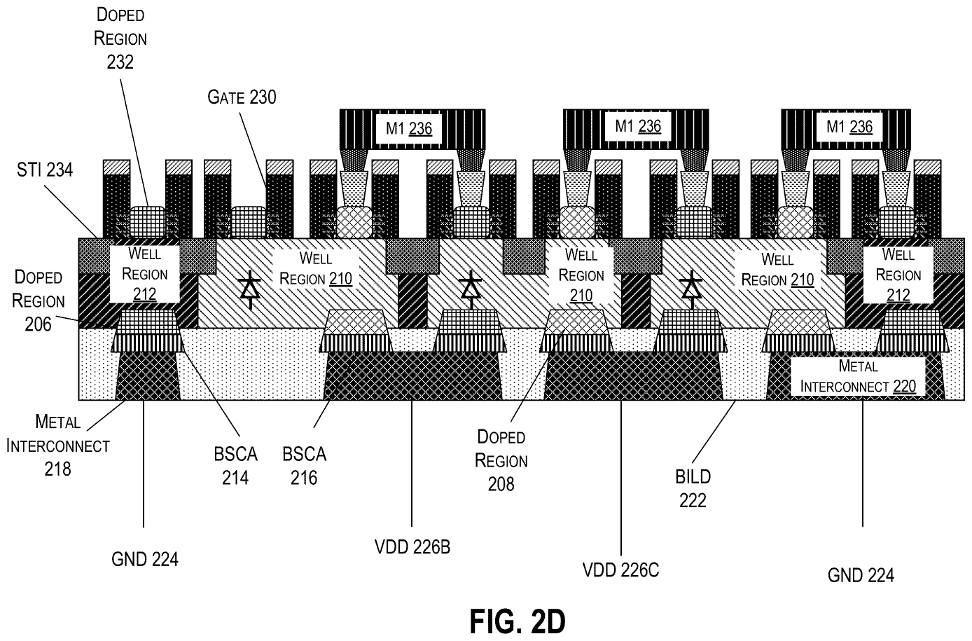

Reference now is made to FIGS. 2A-2B, which are simplified cross-section views of a semiconductor device, consistent with illustrative embodiments. FIG. 2A illustrates a set of diodes, in accordance with some embodiments. The semiconductor device can include a top device 202 positioned on the upper side of the semiconductor device serving as an active component in the circuit. The top device 202 can be a resistor, a field-effect transistor (FET), an N-type capacitor (NCAP), a bipolar junction transistor (BJT), a diode, or a string of diodes with a guard ring. The top device 202 performs electronic functions such as amplification, switching, or signal processing. In some configurations, the top device 202 can function as an electrostatic discharge (ESD) device, protecting the circuit from voltage spikes and static discharge.

Located beneath the top device 202 is the bottom passive device 204, which contributes to the overall functionality of the semiconductor device without actively controlling current flow. The bottom passive device 204 includes a first doped region 206 and a second doped region 208. The first doped region 206 is a P-type doped area where acceptor impurities are introduced to create an abundance of holes, acting as positive charge carriers. The second doped region 208 is an N-type doped area infused with donor impurities to provide an excess of electrons, serving as negative charge carriers. The doped regions intrude at least partially into the first well region 210 and the second well region 212, respectively.

The first well region 210 is an N-well region doped with donor impurities to form an N-type semiconductor area, providing a foundation and isolation for the first doped region 206. The second well region 212 is a P-well region doped with acceptor impurities to establish a P-type semiconductor area, supporting the second doped region 208. The well regions are adjacent to each other and serve to separate the top device 202 from the bottom passive device 204, ensuring electrical isolation and enabling distinct electrical environments within the semiconductor structure.

Below the first doped region 206 is the first backside contact 214, aka BSCA 214, which provides an electrical connection to the P-type doped region from the backside of the wafer. Similarly, below the second doped region 208 is the second backside contact 216, aka BSCA 216, offering electrical connectivity to the N-type doped region from the backside. The backside contacts, aka BSCA, facilitate current flow and enable the operation of the bottom passive device 204 without consuming additional space on the front side of the wafer.

Beneath the backside contacts are the first metal interconnect 218 and the second metal interconnect 220. The first metal interconnect 218 is connected to the first backside contact 214, and the second metal interconnect 220 is linked to the second backside contact 216. The metal interconnects are conductive pathways made of metal, such as copper or aluminum, allowing electrical signals to be transmitted between the backside contacts and other parts of the circuit or external connections. The backside interlayer dielectric 222, aka BILD 222, is an insulating material that isolates the first metal interconnect 218 and the first backside contact 214 from the second metal interconnect 220 and the second backside contact 216. This dielectric layer prevents electrical shorting between the metal interconnects, ensuring that the electrical signals remain distinct and the device operates reliably.

In some implementations, either the top device or the bottom passive device functions as an electrostatic discharge (ESD) device. The ESD device protects the semiconductor components from voltage spikes or static discharge that could cause damage. By integrating the ESD protection into the backside of the device, the design optimizes the use of space on the front side, allowing for more components or reducing the overall size of the semiconductor device. The semiconductor device leverages backside epitaxially grown doped regions and backside wiring to enhance performance and space efficiency. By relocating significant components like the ESD device to the backside, the design reduces (e.g., minimizes) the area occupied on the top wafer surface. This optimization allows for higher levels of integration and additional functionalities without increasing the overall chip size, aligning with the ongoing advancements in semiconductor technology.

The semiconductor device constructs the ESD structure on the bottom side of the wafer, while the main semiconductor devices are built on the top side. This configuration effectively utilizes both sides of the wafer, optimizing space and enhancing the overall functionality of the device. Traditionally, ESD protection components are placed on the top side of the wafer alongside other semiconductor devices. The ESD structures, essential for protecting the device from voltage spikes and static electricity, occupy valuable surface area that could otherwise be used for additional circuitry or more complex device architectures. By relocating the ESD structures to the backside of the wafer, the design frees up significant space on the top side.

This can cause an efficient use of the wafer's backside area to accommodate ESD devices, thereby saving footprint area on the top side for other semiconductor components. The separation allows for a higher density of active devices on the top surface without increasing the overall size of the semiconductor chip. Manufacturers can integrate more functionalities, improve performance, and potentially reduce costs due to the more effective use of available space. Moreover, building ESD structures on the bottom side can lead to better electrical performance. Isolating the ESD components from the main circuitry reduces (e.g., minimizes) interference and parasitic capacitance that could affect the operation of sensitive devices on the top side.

FIG. 2B illustrates a string of diodes using backside wiring, in accordance with some embodiments. The semiconductor device features strings of ESD diodes, or bipolar transistors, built on the top side of the wafer. Parallel to these, an additional string of ESD diodes or bipolars is fabricated on the bottom side of the wafer. This configuration effectively creates two ESD protection pathways within the same physical footprint, significantly enhancing the device's ability to protect sensitive electronic components from voltage spikes and electrostatic discharges. By implementing ESD structures on both sides of the wafer, the design achieves an area efficiency improvement of approximately 50 percent. The efficiency gain arises because two parallel devices are fabricated in the space that would traditionally accommodate a single ESD structure. Utilizing the backside of the wafer for additional circuitry optimizes the available surface area, allowing for more components or functionalities to be included without increasing the overall size of the semiconductor device.

The first doped region 206 can be a P-type doped area within the bottom passive device, introducing positive charge carriers. The second doped region 208 ca be an N-type doped area within the bottom passive device, introducing negative charge carriers. The first well region 210, can be an N-well region providing a foundation and isolation for the first doped region 206, and the second well region 212 can be a P-well region supporting the second doped region 208 and aiding in electrical isolation. The first backside contact 214 is an electrical connection below the first doped region 206 for backside connectivity and the second backside contact 216 is an electrical connection below the second doped region 208 for backside connectivity. The first metal interconnect 218 is a metal pathway connecting the first backside contact 214 to other circuit elements and the second metal interconnect 220 is a metal pathway connecting the second backside contact 216 to other circuit elements. The backside interlayer dielectric 222, e.g., BILD, is an insulating layer isolating metal interconnects and backside contacts to prevent electrical shorting.

The semiconductor device incorporates a design where an Electrostatic Discharge (ESD) structure is built on the top side of the wafer, complemented by a parallel ESD structure fabricated on the bottom side. Such a dual configuration provides two ESD protection paths within the same footprint, significantly enhancing the device's ability to safeguard against voltage spikes and static discharge. By implementing ESD structures on both sides of the wafer, the design achieves an area efficiency improvement of approximately 50%. The efficiency gain is realized because two parallel devices are fabricated in the space that would traditionally accommodate a single ESD structure. Utilizing the backside of the wafer for additional circuitry optimizes the available surface area, allowing for more components or functionalities without increasing the overall size of the semiconductor device. The top device can be an ESD device with gates 230, doped region 232 and shallow trench isolation, STI 234.

Such an approach improves (e.g., maximizes) the use of the wafer's real estate and contributes to improved electrical performance. The parallel ESD structures provide redundant protection, ensuring that sensitive components are safeguarded even if one pathway is compromised. Additionally, distributing the ESD protection across both sides of the wafer can lead to better thermal management, as the heat generated during an ESD event is dissipated more evenly throughout the device. The use of both the top and bottom sides for ESD structures reflects a strategic advancement in semiconductor design.

Such a dual-sided approach enhances the use of the wafer's real estate and contributes to improved electrical performance. The parallel ESD structures provide redundant protection, ensuring that sensitive components are safeguarded even if one pathway becomes compromised. Additionally, distributing the ESD protection across both sides of the wafer can lead to better thermal management. The heat generated during an ESD event is dissipated more evenly throughout the device, reducing thermal stress on any single area and enhancing the overall reliability of the semiconductor device. The use of strings of diodes or bipolar transistors enhances the ESD protection capabilities due to their ability to handle higher currents and voltages. Configuring these devices in a string allows for enhanced control over the breakdown voltage, providing tailored protection levels suitable for various applications. The semiconductor device addresses the industry's demand for higher integration density and enhanced device robustness. By effectively doubling the ESD protection capabilities without increasing the die size, the design offers significant value for applications that require stringent protection against electrostatic events while maintaining compact form factors. It supports the ongoing trend toward miniaturization in electronics, enabling more powerful and reliable devices within smaller packages.

The semiconductor device can include one backside contact serving as the positive supply voltage, VDD 250, and one backside contact serving as an input/output contact, I/O 222, and two additional backside contacts located on opposite ends of the device act as ground, GND 224, connections. Such a configuration optimizes the electrical pathways within the device, allowing for efficient power distribution and signal routing through the backside of the wafer. By assigning these roles to the backside contacts, the design frees up valuable space on the top side of the wafer for other semiconductor components or enhanced functionalities. Furthermore, the second well region 212 in the device acts as a ring around the first well region 210. The P-well ring provides effective isolation for the first well region 210, enhancing the electrical performance and reducing potential interference between different regions of the semiconductor device. The encircling second well region 212 helps to suppress noise and mitigate latch-up issues, which are critical factors in maintaining the reliability and stability of the device, especially in high-density integrated circuits. By utilizing the backside area for power supply (VDD 250), signal I/O, and ground connections, the semiconductor device optimizes area efficiency. The backside implementation of the contacts allows for a more compact design without sacrificing functionality or performance.

FIGS. 2C-2D illustrate a semiconductor device after the front end of line processes, in accordance with some embodiments. In some embodiments, the semiconductor device includes multiple, e.g., three, PN diode strings with a guard ring connected with parallel topside and bottom doped region junctions. The semiconductor device can include strings of ESD diodes or bipolar transistors constructed on both the top and bottom sides of the wafer. On the top side, a series of ESD diodes or bipolar transistors are arranged in a string configuration. Parallel to this arrangement, an identical string of ESD diodes or bipolar transistors is fabricated on the bottom side of the wafer. The dual-sided configuration creates two parallel ESD protection pathways within the same physical footprint. By utilizing both sides of the wafer for ESD structures, the design enhances the device's ability to protect sensitive electronic components from voltage spikes and electrostatic discharges without increasing the overall size of the semiconductor chip.

The implementation of ESD structures on both the top and bottom sides result in improved area efficiency. Since two parallel devices are fabricated in the space that would traditionally accommodate a single ESD structure, the design achieves significant improvement in area utilization. The efficient use of space allows for the integration of additional functionalities or a higher density of active devices on the top surface, supporting the development of more compact and powerful electronic components. Moreover, the parallel ESD structures provide redundant protection, ensuring that the device remains safeguarded even if one pathway becomes compromised. The redundancy enhances the reliability and robustness of the semiconductor device, which is important in applications where ESD events can cause significant damage to sensitive circuitry.

The use of strings of diodes or bipolar transistors is effective in handling higher currents and voltages associated with ESD events. Configuring the devices in a string allows for control over the breakdown voltage and enables the tailoring of protection levels to specific requirements. Additionally, by fabricating ESD structures on both sides of the wafer, the design improves thermal management. Heat generated during an ESD event can dissipate more evenly across the device, reducing thermal stress on any single area and enhancing the overall reliability of the semiconductor device.

The first doped region 206 can be a P-type doped area within the bottom device, introducing positive charge carriers. The second doped region 208 ca be an N-type doped area within the bottom device, introducing negative charge carriers. The first well region 210, can be an N-well region providing a foundation and isolation for the first doped region 206, and the second well region 212 can be a P-well region supporting the second doped region 208 and aiding in electrical isolation. The first backside contact 214 is an electrical connection below the first doped region 206 for backside connectivity and the second backside contact 216 is an electrical connection below the second doped region 208 for backside connectivity. The first metal interconnect 218 is a metal pathway connecting the first backside contact 214 to other circuit elements and the second metal interconnect 220 is a metal pathway connecting the second backside contact 216 to other circuit elements. The backside interlayer dielectric 222, e.g., BILD, is an insulating layer isolating metal interconnects and backside contacts to prevent electrical shorting.

The semiconductor device incorporates a design where an Electrostatic Discharge (ESD) structure is built on the top side of the wafer, complemented by a parallel ESD structure fabricated on the bottom side. Such a dual configuration provides two ESD protection paths within the same footprint, significantly enhancing the device's ability to safeguard against voltage spikes and static discharge. By implementing ESD structures on both sides of the wafer, the design achieves an area efficiency improvement of approximately 50%. The efficiency gain is realized because two parallel devices are fabricated in the space that would traditionally accommodate a single ESD structure. Utilizing the backside of the wafer for additional circuitry optimizes the available surface area, allowing for more components or functionalities without increasing the overall size of the semiconductor device. The top device can be an ESD device with gates 230, doped region 232 and shallow trench isolation, STI 234. Metal interconnect, M1 236, connects the frontside of the semiconductor device to other devices.

The semiconductor device can optimize both space utilization and electrical performance by incorporating backside contacts and shared metal interconnects. The semiconductor device includes two backside contacts located at opposite ends, which serve as ground (GND) connections, GND 224. Such ground contacts are positioned on the backside of the wafer, allowing for efficient grounding without consuming valuable space on the top side where active components are situated.

In addition to the ground contacts, the semiconductor device incorporates three backside contacts designated as Vdd, VDD 226A, VDD 226B, VDD 226C, which provide the positive supply voltage necessary for the operation of the semiconductor components. By placing both the Vdd and GND contacts on the backside of the wafer, the design frees up the area on the top side. This space can then be utilized for additional semiconductor devices or for enhancing the complexity and functionality of existing components. One or more of the metal interconnects within the semiconductor device are designed to be shorted and shared by backside contacts of opposite doping types. Specifically, the shared metal interconnects connect both N-type and P-type doped regions. This configuration reduces the number of individual interconnects required, thereby simplifying the circuitry and conserving space. The shared interconnects facilitate efficient signal routing and power distribution throughout the device, contributing to improved electrical performance.

A feature of the design is the use of a P-well that acts as a collector ring around an N-well. This P-well collector ring, P-well 210A, provides effective isolation for the N-well, enhancing the electrical characteristics of the device by reducing parasitic interactions and suppressing leakage currents. The encircling P-well ensures that the N-well operates within its intended electrical parameters, which is crucial for the reliability and efficiency of the semiconductor device.

Each shared metal interconnect can be connected to N-well contacts, further optimizing the layout by reducing (e.g., minimizing) the need for additional interconnects dedicated solely to N-well regions. The shared approach can conserve space and reduce the complexity of the manufacturing process, potentially lowering production costs and improving yield. By locating the ground contacts on the backside of the semiconductor device, the thermal management and electromagnetic compatibility are enhanced.

As shown in FIG. 2D, in some embodiments, the semiconductor device incorporates a dual-sided design where strings of ESD diodes or bipolar transistors are constructed on both the top and bottom sides of the wafer. On the top side, a series of ESD diodes or bipolar transistors are arranged in a string configuration. Simultaneously, an integrated string of ESD diodes or bipolar transistors is fabricated on the bottom side of the wafer. Such a bottom-side integration mirrors the ESD protection provided on the top side, effectively creating parallel ESD protection pathways within the same semiconductor device. By utilizing both sides of the wafer for ESD structures, the design optimizes the use of available space, enhancing area efficiency without increasing the overall size of the chip.

This dual-sided approach provides redundant ESD protection mechanisms. If one ESD pathway is compromised due to a defect or an exceptionally strong electrostatic event, the parallel pathway on the opposite side can continue to protect the device. This redundancy enhances the reliability and robustness of the semiconductor device, which is crucial in applications where device failure due to ESD events is unacceptable. Further, by integrating ESD structures on the bottom side of the wafer, valuable surface area on the top side is freed up. This additional space can be utilized to incorporate more complex circuitry, add new functionalities, or increase the density of active devices. This efficient use of space aligns with the industry's ongoing efforts to create smaller, more powerful, and more efficient electronic components.

The use of strings of diodes or bipolar transistors allows for precise control over the breakdown voltage and the tailoring of ESD protection levels to meet specific requirements. Configuring these devices in a string enhances their ability to handle higher currents and voltages associated with ESD events. This embodiment utilizes both sides of the wafer to enhance ESD protection and area efficiency. The integration of ESD diodes or bipolar transistors on the bottom side, in parallel with those on the top side, allows for higher levels of integration and functionality without increasing the chip's footprint.

The first doped region 206 can be a P-type doped area within the bottom device, introducing positive charge carriers. The second doped region 208 ca be an N-type doped area within the bottom device, introducing negative charge carriers. The first well region 210, can be an N-well region providing a foundation and isolation for the first doped region 206, and the second well region 212 can be a P-well region supporting the second doped region 208 and aiding in electrical isolation. The first backside contact 214 is an electrical connection below the first doped region 206 for backside connectivity and the second backside contact 216 is an electrical connection below the second doped region 208 for backside connectivity. The first metal interconnect 218 is a metal pathway connecting the first backside contact 214 to other circuit elements and the second metal interconnect 220 is a metal pathway connecting the second backside contact 216 to other circuit elements. The backside interlayer dielectric 222, e.g., BILD, is an insulating layer isolating metal interconnects and backside contacts to prevent electrical shorting.

The semiconductor device incorporates a design where an Electrostatic Discharge (ESD) structure is built on the top side of the wafer, complemented by a parallel ESD structure fabricated on the bottom side. Such a dual configuration provides two ESD protection paths within the same footprint, significantly enhancing the device's ability to safeguard against voltage spikes and static discharge. By implementing ESD structures on both sides of the wafer, the design achieves an area efficiency improvement of approximately 50%. The efficiency gain is realized because two parallel devices are fabricated in the space that would traditionally accommodate a single ESD structure. Utilizing the backside of the wafer for additional circuitry optimizes the available surface area, allowing for more components or functionalities without increasing the overall size of the semiconductor device. The top device can be an ESD device with gates 230, doped region 232 and shallow trench isolation, STI 234. Metal interconnect, M1 236, connects the frontside of the semiconductor device to other devices.

Example Fabrication of a Semiconductor Device with Backside Wiring Structure

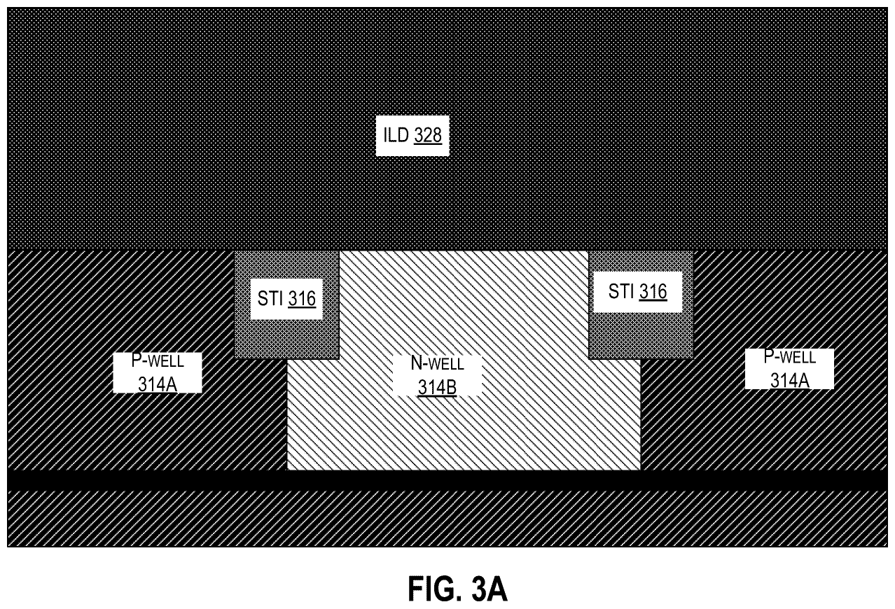

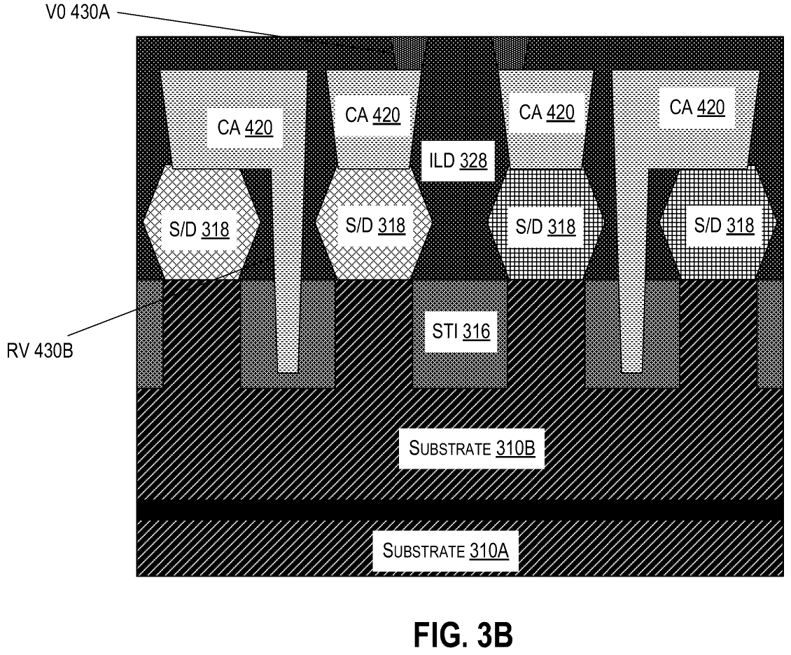

With the foregoing description of an example semiconductor device, it may be helpful to discuss an example process of manufacturing the same. To that end, FIGS. 3-12 illustrate various acts in the manufacture of a semiconductor device, consistent with illustrative embodiments. Figures denoted by A depict the passive region and figures denoted by B depict the transistor region of the semiconductor device.

FIGS. 3A-3B illustrate a semiconductor device after the front end of line processes, in accordance with some embodiments. The semiconductor can include a first substrate 310A, an etch stop layer 312, a second substrate 310B, a P-well 314A, an N-well 314B, shallow trench isolation, STI 316, interlayer dielectric, ILD 328, and source/drain regions, S/D 318.

In the illustrative example depicted in FIGS. 3A-3B, the semiconductor device is depicted as being on silicon as the first substrate 310A and the second substrate 310B, while it will be understood that other types as the first substrate 310A and the second substrate 310B can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AIIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 310A and the second substrate 310B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 312 is formed between the first substrate 310A and the second substrate 310B. The etch stop layer 312 can be a thin layer of material incorporated into the structure of the semiconductor device to provide a selective barrier against etching processes, preventing further removal of underlying materials during fabrication. The etch stop layer 312 can enable precise control over the etching depth and help define the desired device dimensions. The etch stop layer 312 can further provide a stopping point for the etching process, ensuring that specific layers or regions are not etched beyond a certain point, leading to accurate patterning and control of critical features. The etch stop layer 312 can create a distinct separation between different layers or components within the device structure, and prevent the undesired etching of underlying layers or materials, enabling the creation of complex, multi-layered structures with well-defined interfaces and boundaries. In some embodiments, the etch stop layer 312 acts as a protective barrier for sensitive or delicate materials to shield such materials from aggressive etchants, preventing damage or degradation during subsequent fabrication steps.

In some embodiments, prior to forming the etch stop layer 312, the first substrate 310A and/or the second substrate 310B is prepared by cleaning and removing any impurities or oxide layers. The etch stop layer 312 is deposited onto the first substrate 310A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 312 can then be selectively etched, stopping at a predetermined depth, while protecting the underlying layers. After the etching process, the remaining photoresist can be removed through stripping techniques. While in some embodiments, SiGe is used to form the etch stop layer 312, in some embodiments, silicon nitride (SiN), silicon oxide (SiO₂), or silicon oxynitride (SiON) can be used as the etch stop layer 312.

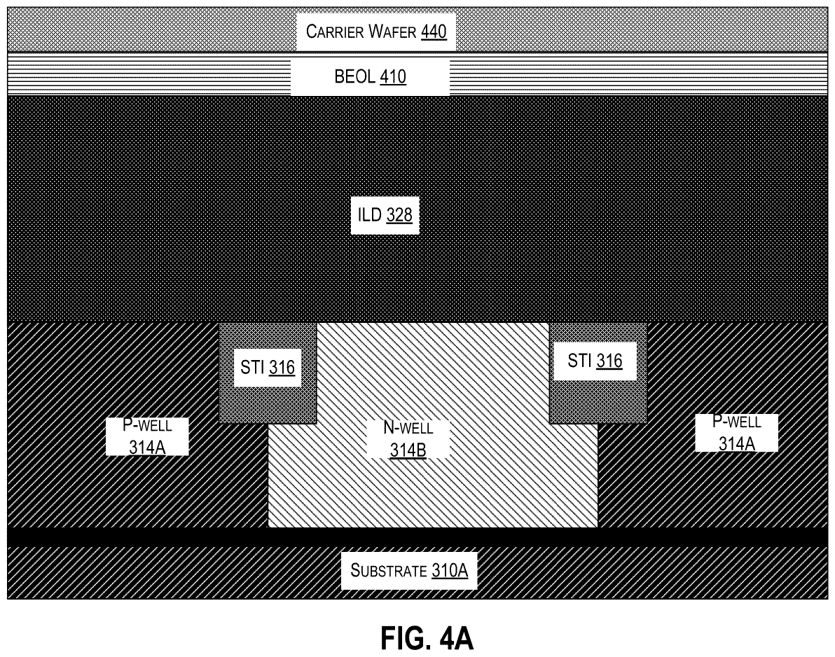

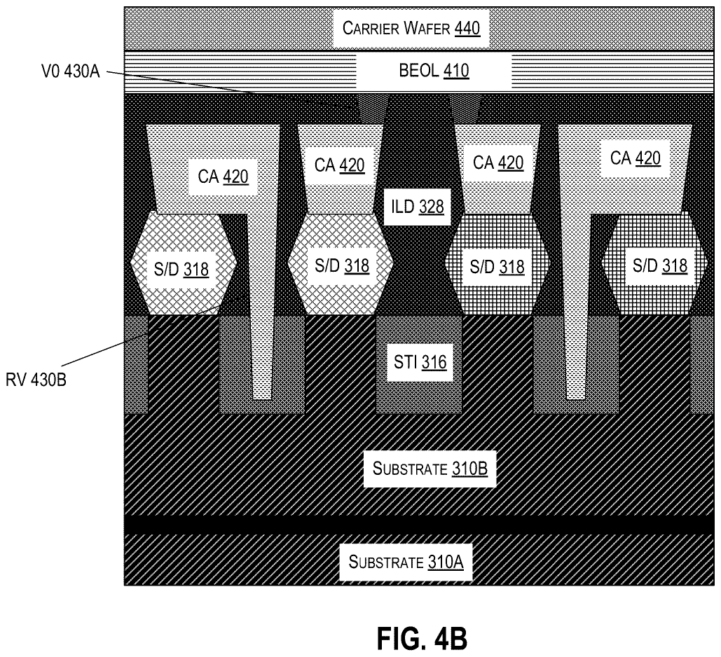

Reference now is made to FIGS. 4A-4B illustrate a semiconductor device after the middle end of line and back end of line processes, in accordance with some embodiments. In some embodiments, the middle of line is performed. The back end of line, BEOL 410, the frontside contacts, CA 420, and vias, V0 430A and RV 430B, are formed. In various embodiments, carrier wafer bonding, also known as wafer-to-wafer bonding or chip-to-wafer bonding, is performed to join two semiconductor devices together by creating a permanent bond between them via a carrier wafer 440. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

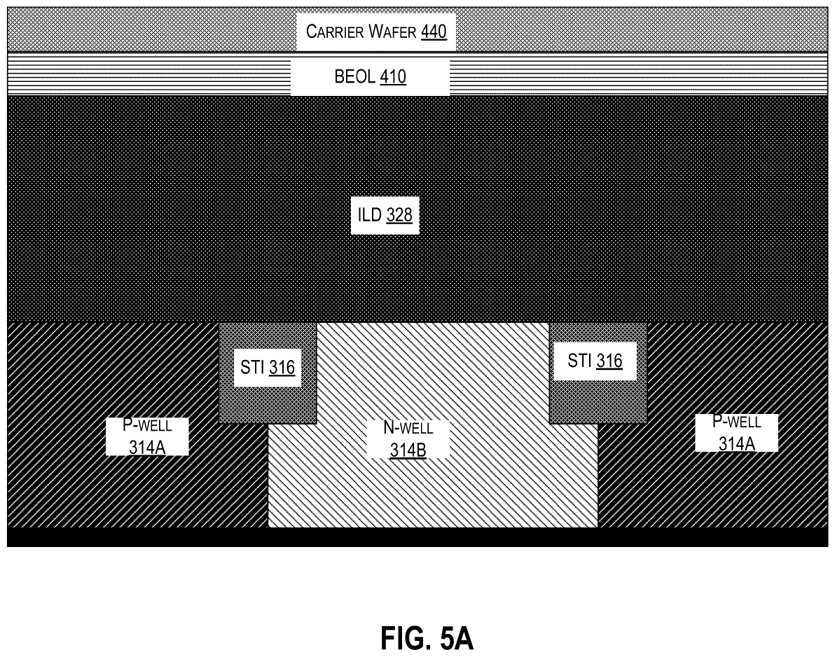

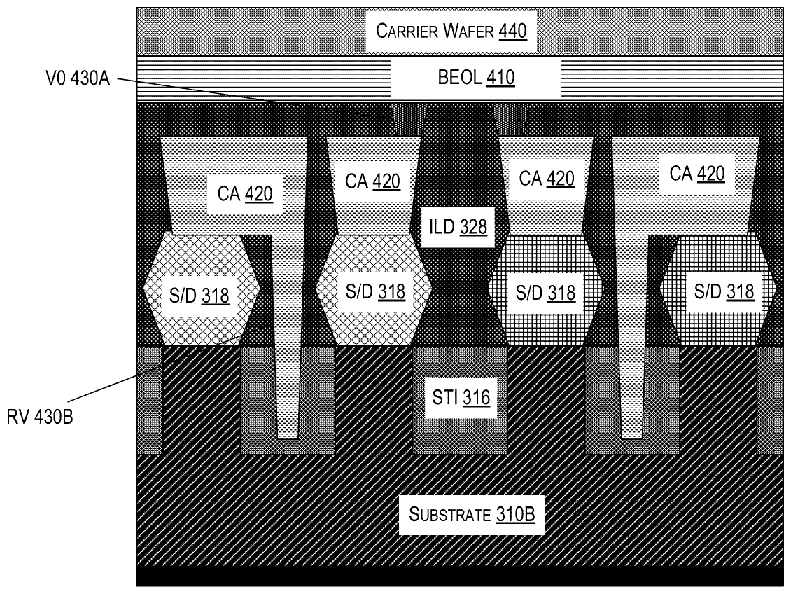

FIGS. 5A-5B illustrate a semiconductor device after the removal of the substrate, in accordance with some embodiments. In some embodiments, the first substrate is removed and the etch stop layer 312 is exposed.

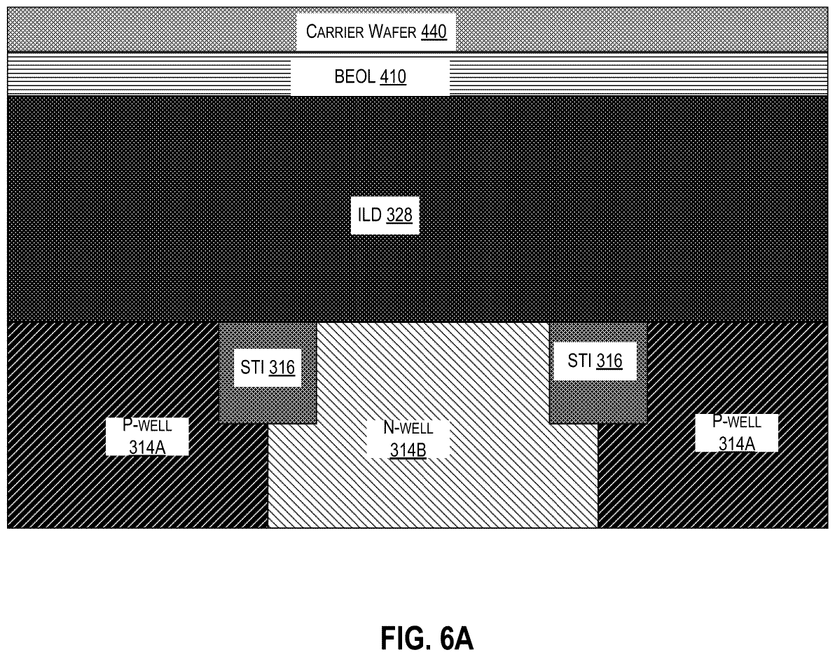

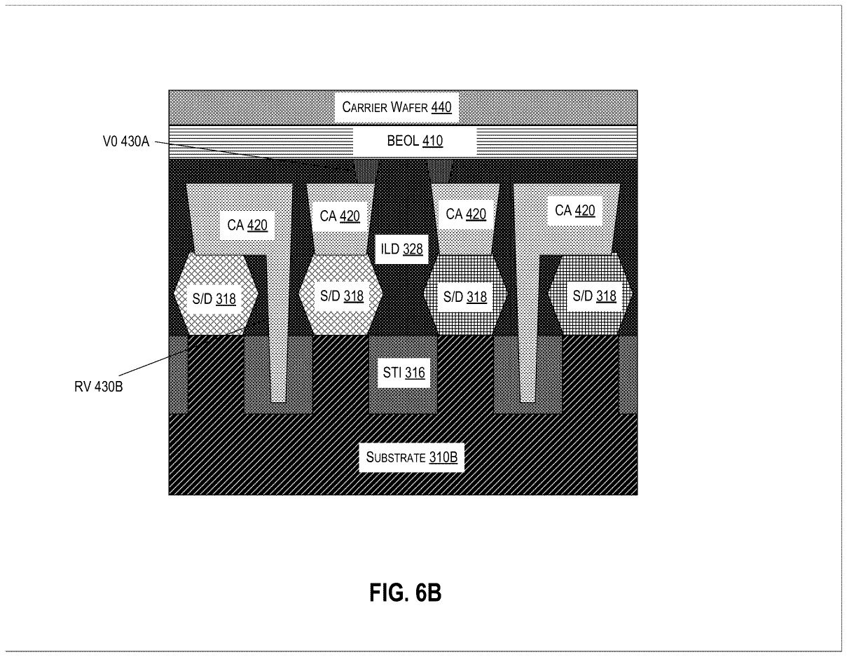

FIGS. 6A-6B illustrate a semiconductor device after the removal of the etch stop layer, in accordance with some embodiments. In some embodiments, the etch stop layer is removed.

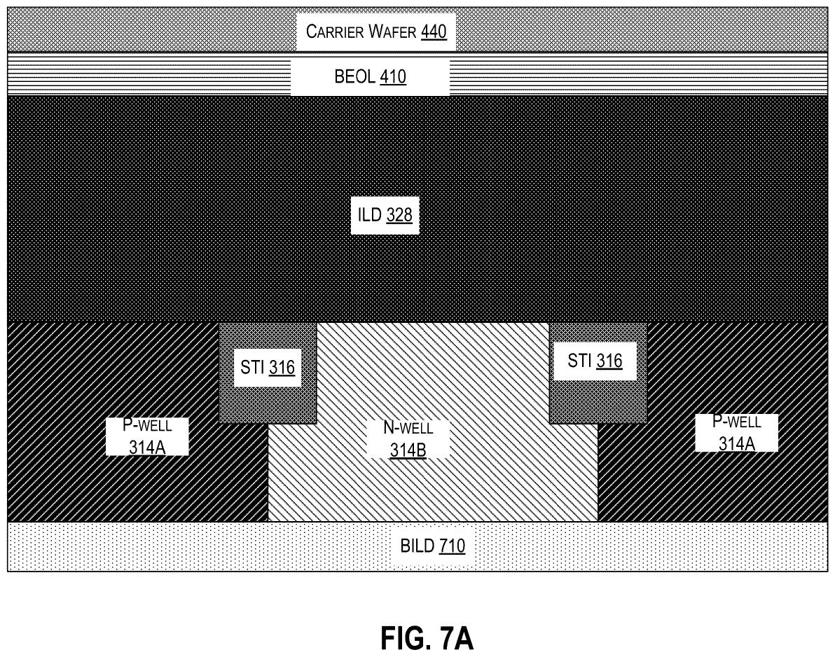

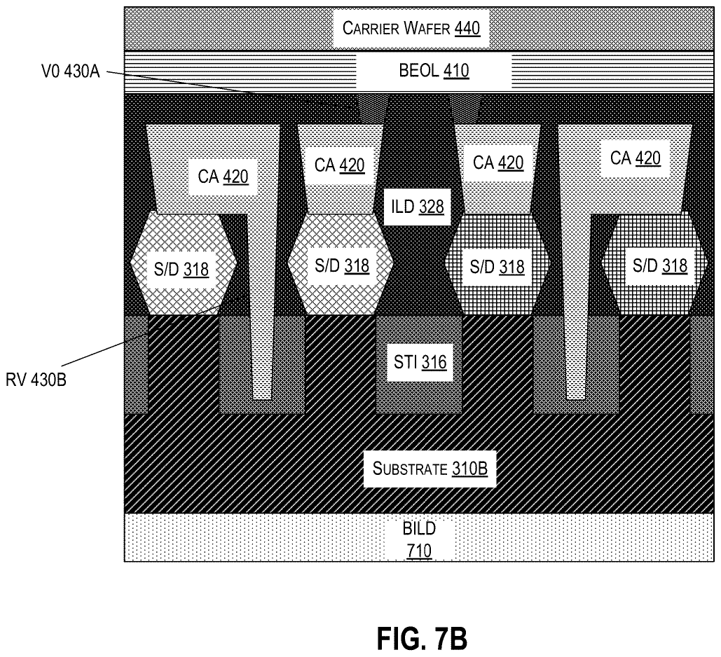

FIGS. 7A-7B illustrate a semiconductor device after the formation of the backside interlayer dielectric, in accordance with some embodiments. In some embodiments, a BILD 710 is formed over the backside of the semiconductor device.

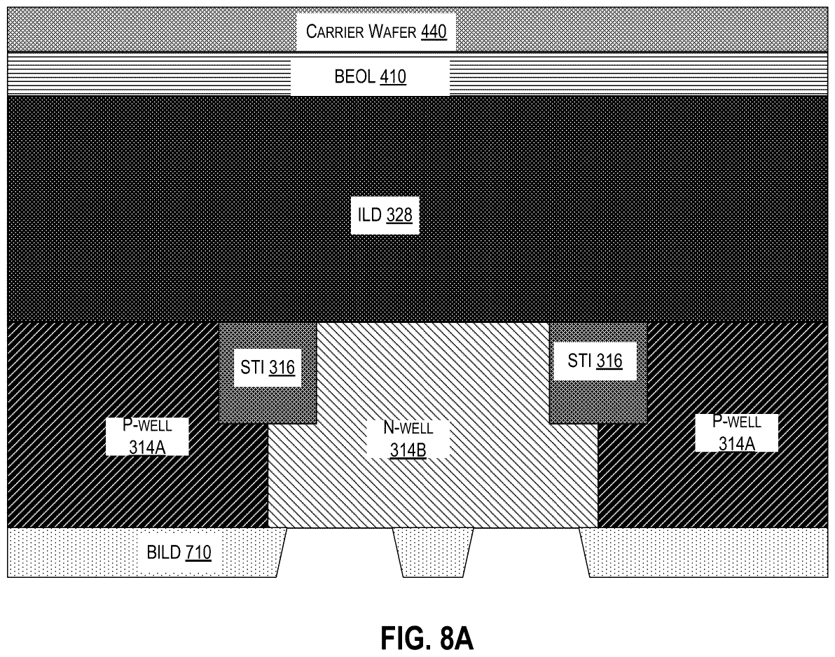

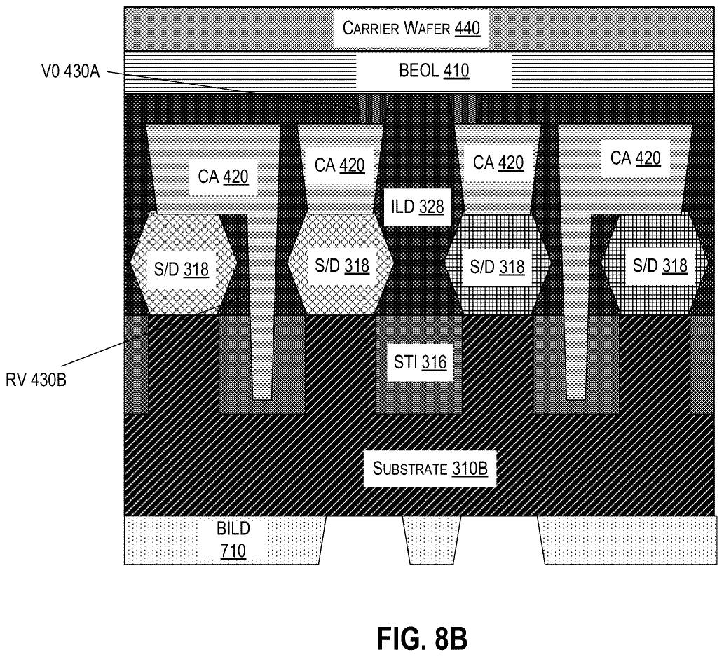

FIGS. 8A-8B illustrate a semiconductor device after patterning of the backside doped regions, in accordance with some embodiments. In some embodiments, portions of the BILD are removed to expose the N-well in the passive region.

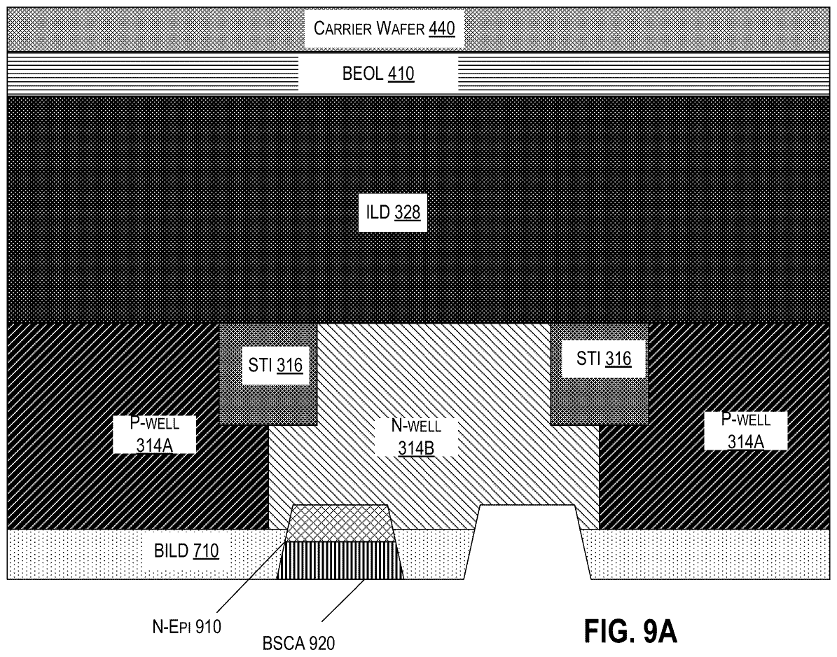

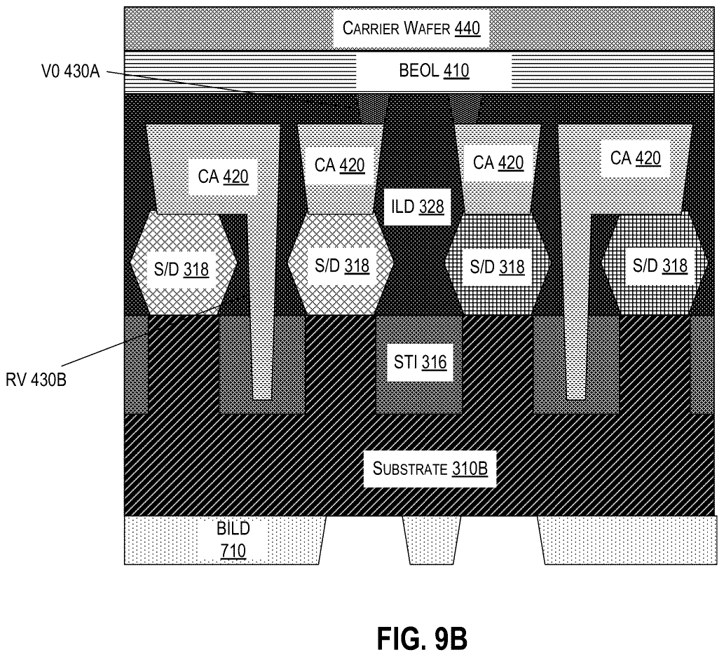

FIGS. 9A-9B illustrate a semiconductor device after the contact metallization, in accordance with some embodiments. In some embodiments, an N-type trench, N-epi 910, is formed at a low temperature, followed by the formation of a backside contact, BSCA 920.

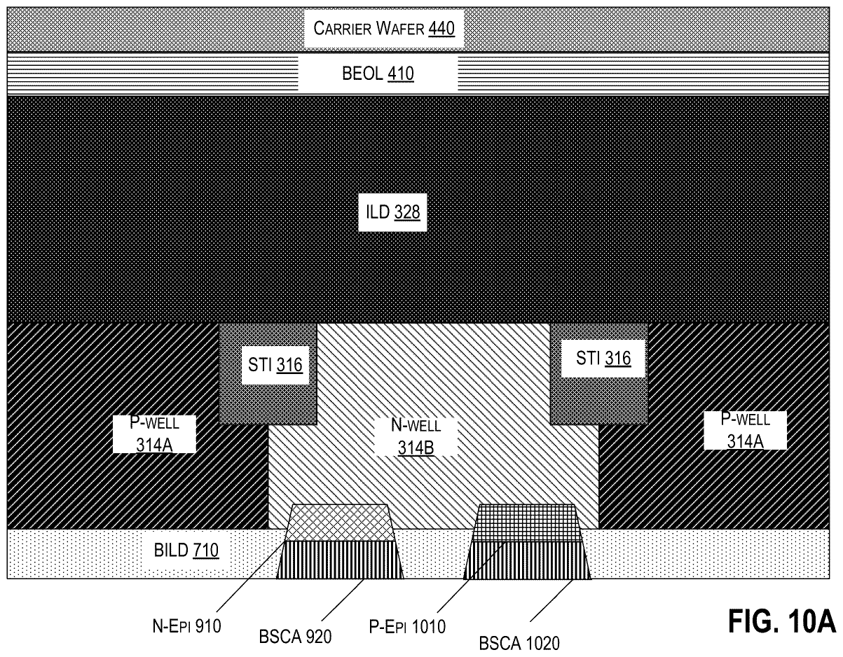

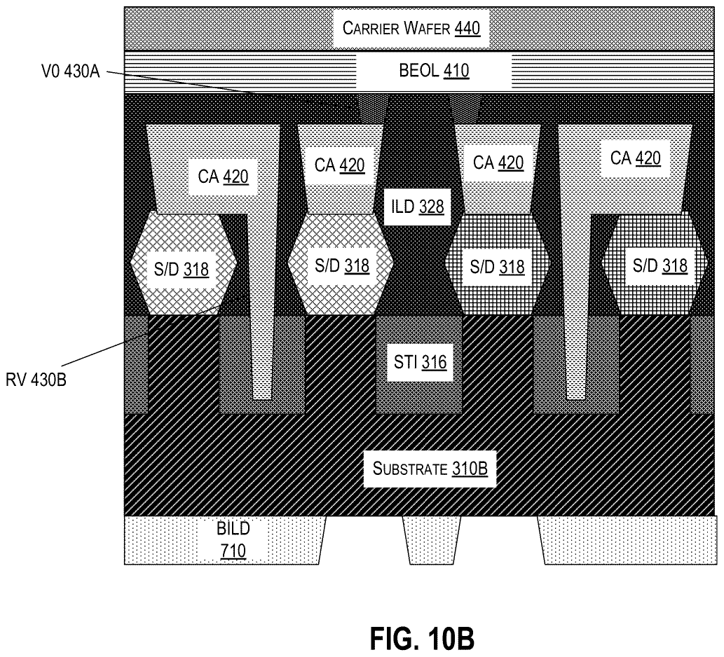

FIGS. 10A-10B illustrate a semiconductor device after the contact metallization, in accordance with some embodiments. In some embodiments, a P-type trench, P-epi 1010, is formed at a low temperature, followed by the formation of a backside contact, BSCA 1020.

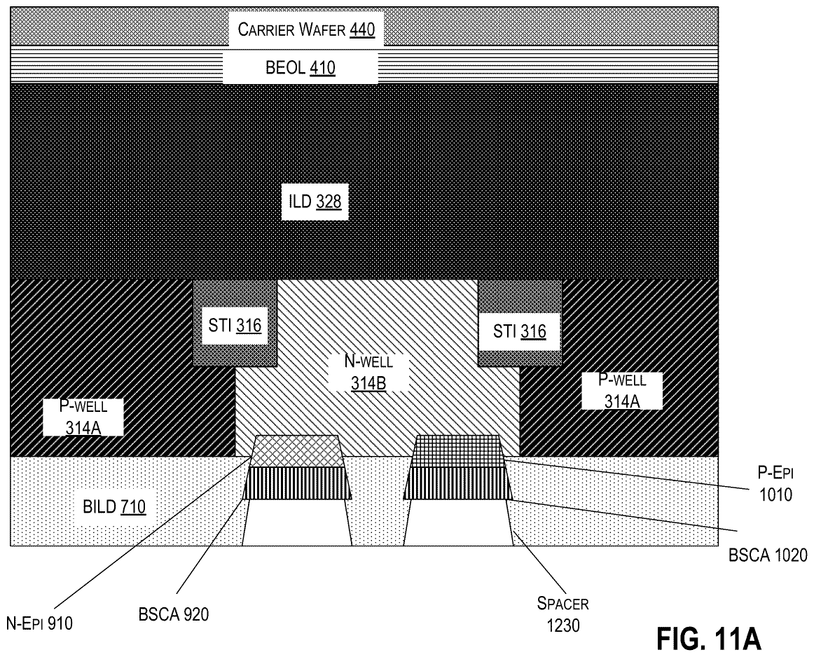

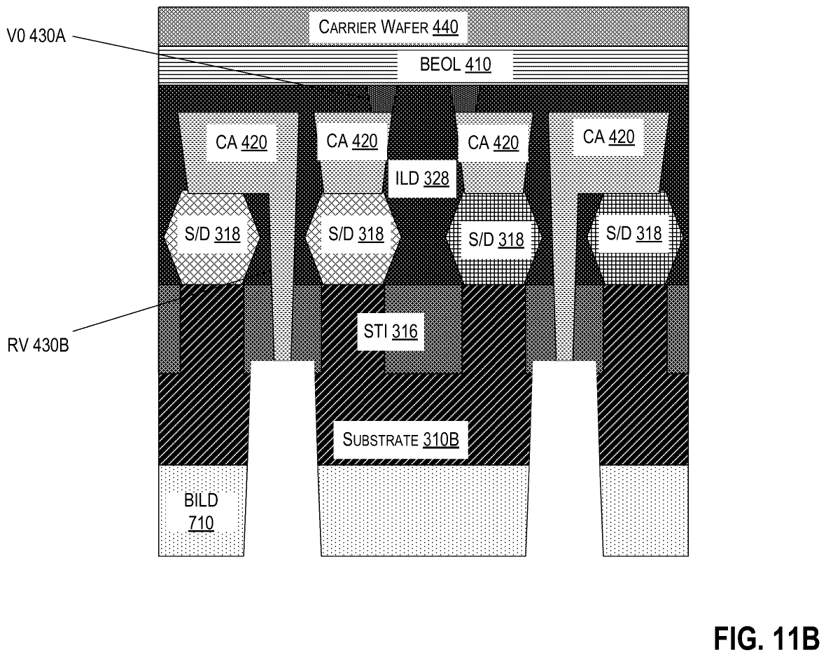

FIGS. 11A-11B illustrate a semiconductor device after the formation of additional interlayer dielectric, in accordance with some embodiments. In some embodiments, additional BILD is formed over the backside of the semiconductor device. Portions of the BILD over the backside contacts, BSCA 920 and BSCA 1020, and portions of the BILD over the RV 430B are removed from the passive region 1100A and the transistor region 1100B, respectively.

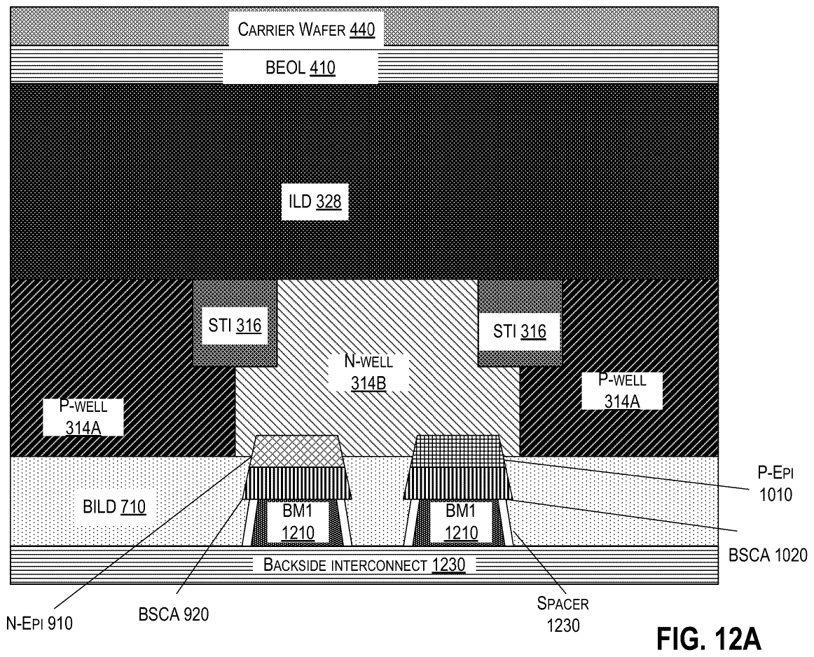

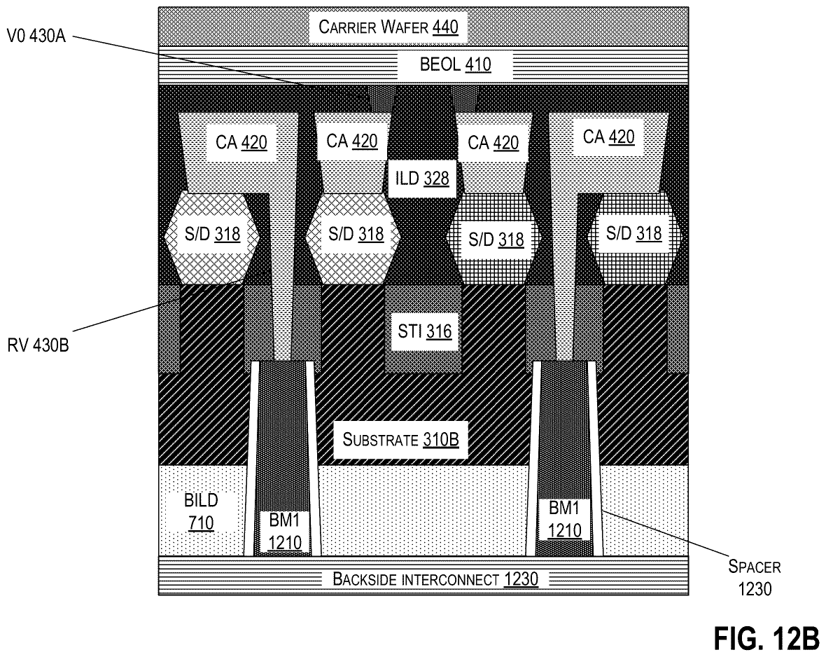

FIGS. 12A-12B illustrate a semiconductor device after the formation of backside interconnect, in accordance with some embodiments. In some embodiments, backside metals, BM 1210, are formed over the backside contacts, BSCA 920 and BSCA 1020, and the RV 430B, in the passive region 1200A and the transistor region 1200B, respectively. A spacer 1220 is formed over the BM1 1210. A backside interconnect 1230 is formed over the backside of the semiconductor device.

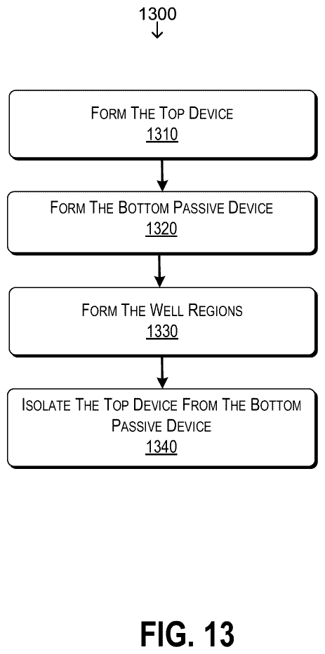

FIG. 13 illustrates a block diagram of a method 1300 for forming the semiconductor device, in accordance with some embodiments. As shown by block 1310, a top device is formed.

As shown by block 1320, a bottom passive device is formed.

As shown by block 1330, a first well region and a second well region are formed adjacent to each other.

As shown by block 1340, the top device is isolated from the bottom passive device via the first well region and the second dwell region.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a top device;
a bottom passive device; and
a first well region and a second well region adjacent to each other and separating the top device from the bottom passive device.

2. The semiconductor device of claim 1, wherein the bottom passive device comprises:
a first doped region;
a second doped region;
a first backside contact below the first doped region; and
a second backside contact below the second doped region,
wherein the first doped region and the second doped region are at least partially intruding into the first well region and the second well region, respectively.

3. The semiconductor device of claim 2, wherein the bottom passive device further comprises:
a first metal interconnect below the first backside contact;
a second metal interconnect below the second backside contact; and
a backside interlayer dielectric isolating the first metal interconnect and the first backside contact from the second metal interconnect and the second backside contact.

4. The semiconductor device of claim 1, wherein the top device is at least one of: a resistor, a field-effect transistor, and an N-type capacitor.

5. The semiconductor device of claim 1, wherein at least one of the top device and the bottom passive device is an electrostatic discharge device (ESD).

6. The semiconductor device of claim 1, wherein the top device includes at least one of: a bipolar junction and a diode.

7. The semiconductor device of claim 1, wherein the top device includes a string of diodes with a guard ring.

8. The semiconductor device of claim 1, wherein the first well region is an N-well region and the second well region is a P-well region.

9. The semiconductor device of claim 2, wherein the first doped region is a P-type doped region, and the second doped region is an N-type doped region.

10. A method for fabrication of a semiconductor device, the method comprising:
forming a top device;
forming a bottom passive device;
forming a first well region and a second well region adjacent to each other; and
isolating the top device from the bottom passive device via the first well region and the second well region.

11. The method of claim 10, wherein forming the bottom passive device comprises:
forming a first doped region;
forming a second doped region;
forming a first backside contact below the first doped region;
forming a second backside contact below the second doped region; and
at least partially extending the first doped region and the second doped region into the first well region and the second well region, respectively.

12. The method of claim 11, wherein the forming bottom passive device further comprises:
forming a first metal interconnect below the first backside contact;
forming a second metal interconnect below the second backside contact;
forming a backside interlayer dielectric; and
isolating the first metal interconnect and the first backside contact from the second metal interconnect and the second backside contact via the backside interlayer dielectric.

13. The method of claim 10, wherein the top device is at least one of: a resistor, a field-effect transistor, and an N-type capacitor.

14. The method of claim 10, wherein at least one of the top device and the bottom passive device is an electrostatic discharge device (ESD).

15. The method of claim 10, wherein the top device includes at least one of: a bipolar junction and a diode.

16. The method of claim 10, wherein forming the top device further comprises forming a string of diodes with guard rings.

17. The method of claim 10, further comprising:
doping the first well region with an N-type dopant; and
doping the second well region with a P-type dopant.

18. The method of claim 11, further comprising:
doping the first doped region with an N-type dopant; and
doping the second doped region with a P-type dopant.

19. A semiconductor device, comprising:
a top electrostatic discharge (ESD) device; and
a bottom ESD device, wherein the top ESD device is built on a frontside of the semiconductor device and the bottom ESD device is built on a backside of the semiconductor device.

20. The semiconductor device of claim 19, further comprising:
a first well region and a second well region adjacent to each other and separating the top ESD device from the bottom ESD device.
